(19) United States
(12) Patent Application Publication
(10) Pub. No.: US 2026/0323919 A1
(43) Pub. Date: Oct. 15, 2026

(54) SEMICONDUCTOR DEVICE

(71) Applicant: SK hynix Inc., Icheon-si (KR)

(72) Inventor: Heon Yong CHANG, Icheon-si (KR)

(21) Appl. No.: 19/286,999

(22) Filed: Jul. 31, 2025

(30) Foreign Application Priority Data
Apr. 10, 2025 (KR) 10-2025-0046476

(51) Int. Cl. H10B 12/00; H10B 80/00; H10D 80/30; H10W 90/00; H10W 90/20

(52) U.S. Cl. CPC H10B 12/33; H10B 12/09; H10B 12/482; H10B 80/00; H10D 80/30; H10W 90/00; H10W 90/297; H10W 90/792

(57) ABSTRACT

A semiconductor device includes a first semiconductor structure and a second semiconductor structure that are bonded to each other by a bonding layer. The first semiconductor structure includes a capacitor including a plate electrode, a channel structure disposed on the capacitor, a bit line disposed on the channel structure, a first upper wiring layer disposed on the bit line, a first wiring layer positioned between the first upper wiring layer and a layer in which the plate electrode is located, and a lower contact connecting the plate electrode and the first wiring layer.

The present application claims priority under 35 U.S.C. 119(a) to Korean patent application number 10-2025-0046476 filed on Apr. 10, 2025, which are incorporated herein by reference in its entirety.

### BACKGROUND

### 1. Technical Field

Various embodiments relate to a semiconductor device.

### 2. Related Art

Due to characteristics such as miniaturization, multifunctionality, and/or low production costs, semiconductor devices are attracting attention as important components in the electronics industry. As the electronics industry advances, semiconductor devices are becoming increasingly highly integrated. To achieve high integration of memory devices, line widths of wires included in semiconductor devices are gradually decreasing, and accordingly, the difficulty of processes of forming the semiconductor devices is increasing.

For high integration of semiconductor devices, a process of separately fabricating a wafer on which memory cells are arranged and a wafer on which peripheral circuits are arranged, and bonding the wafers together, is employed. In the case of manufacturing semiconductor devices by bonding the wafers, it is necessary to form various wires and contacts for electrical connection between the memory cells and the peripheral circuits.

### SUMMARY

Objects of embodiments are not limited to the objects described herein, and other objects that are not described will be clearly understood by a person skilled in the art from the description below.

Various embodiments are directed to a semiconductor device configured such that electrical connection failures between memory cells and a peripheral circuit are prevented.

In an embodiment, a semiconductor device comprising: a first semiconductor structure and a second semiconductor structure that are bonded to each other by a bonding layer. The first semiconductor structure may include a capacitor including a plate electrode disposed in a plate electrode layer, a channel structure disposed on the capacitor to extend in a vertical direction, a bit line spaced apart from the capacitor in the vertical direction and disposed on the channel structure and in a bit line layer, a first upper wiring layer disposed on the bit line, a first wiring layer positioned between the first upper wiring layer and the plate electrode layer, and a lower contact connecting the plate electrode and the first wiring layer.

In an embodiment, a semiconductor device may include a substrate, a first upper wiring layer disposed on the substrate, a capacitor positioned between the substrate and the first upper wiring layer, the capacitor including a plate electrode, a channel structure disposed on the capacitor to extend in a vertical direction, a bit line spaced apart from the capacitor in the vertical direction and disposed on the channel structure, a first wiring layer extending from a cell area to a peripheral area and positioned between the first upper wiring layer and a layer in which the plate electrode is located, and a lower contact connecting the plate electrode and the first wiring layer.

In an embodiment, a semiconductor device may include a first semiconductor structure, a second semiconductor structure bonded to the first semiconductor structure and the first semiconductor structure comprises a cell region and a peripheral region, the cell region of the first semiconductor structure comprises a channel structure formed at a first level, a bit line disposed on a second level, the second level is higher than the first level and a capacitor disposed on a third level, the third level is lower than the first level.

Various embodiments may provide a semiconductor device configured such that electrical connection failures between memory cells and a peripheral circuit are prevented.

Effects of various embodiments are not limited to those mentioned above, and other effects not explicitly described herein will be clearly understood by those skilled in the art from the scope of the claims.

### BRIEF DESCRIPTION OF THE DRAWINGS

The present disclosure will be more fully understood from the following detailed description and the accompanying drawings. The description and the drawings are provided for illustrative purposes only and are not intended to limit the scope of the present disclosure.

FIG. 1 is a diagram illustrating an example of a cross-sectional structure of a semiconductor device according to an embodiment.

FIG. 2 is a diagram illustrating another example of the cross-sectional structure of the semiconductor device according to an embodiment.

FIGS. 3-11 are diagrams illustrating an example of a method of manufacturing the semiconductor device according to an embodiment disclosed in FIG. 1.

FIGS. 12-19 are diagrams illustrating an example of a method of manufacturing the semiconductor device according to the embodiment disclosed in FIG. 2.

### DETAILED DESCRIPTION

Hereinafter, various embodiments will be described in detail with reference to the accompanying drawings. In the following description, like reference numerals may be used to designate the same components although the components are shown in different drawings. Furthermore, in the following description, a detailed description of known functions and configurations incorporated herein will be omitted when it may make the subject matter of the disclosure rather unclear. The terms such as “including,” used herein are generally intended to allow other components to be added unless the terms are used with the term “only”. Any references to singular may include plural unless expressly stated otherwise.

Also, in describing the components of the disclosure, there may be terms used like first and second. These are solely for the purpose of differentiating one component from the other but not to imply or suggest the substances, order, sequence or number of the components.

In descriptions for the positional relationships of components, in the case where it is described that at least two components are “connected,” or “coupled,” it is to be understood that the at least two components may be directly “connected,” or “coupled” but may be indirectly “connected,” or “coupled” with another component interposed between the two components. Here, another component may be included in at least one of the at least two components which are “connected,” or “coupled” with each other.

In the case where a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments will be described in detail with reference to accompanying drawings.

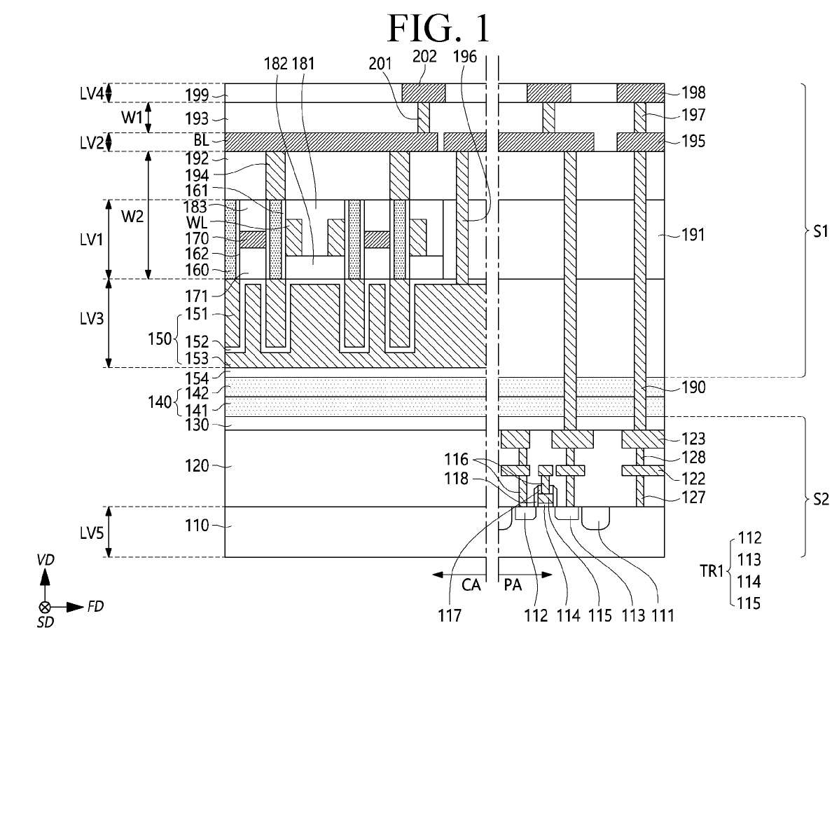

FIG. 1 is a diagram illustrating an example of a cross-sectional structure of a semiconductor device according to an embodiment.

Referring to FIG. 1, the semiconductor device according to an embodiment may include a first semiconductor structure S1, a second semiconductor structure S2, a bonding layer 140, and a through contact 190.

The first semiconductor structure S1 may include a third insulating layer 154, a capacitor 150, a channel structure 160, a second gate insulating layer 161, a third gate insulating layer 162, a back gate electrode 170, a second gate capping layer 171, a first insulating pattern 181, a second insulating pattern 182, a third insulating pattern 183, a word line WL, a fourth insulating layer 191, a fifth insulating layer 192, a sixth insulating layer 193, a seventh insulating layer 199, a bit line contact 194, a bit line BL, a lower contact 196, a wiring contact 197, wiring layers 195 and 198, a first upper contact 201, and a first upper wiring layer 202.

In an embodiment, the first upper contact 201 is in direct contact with an upper surface of the bit line BL. In the present specification, a structure that is in direct contact with the upper surface of the bit line BL may be referred to as a connection contact. Referring to FIG. 1, the first upper contact 201 may be the connection contact.

The second semiconductor structure S2 may include a substrate 110, an element isolation layer 111, a lower transistor TR1, a first gate capping layer 117, a spacer 118, a first insulating layer 120, a lower wiring layer 122, a pad layer 123, contacts 116, 127, and 128, and a second insulating layer 130.

The bonding layer 140 may include a first bonding insulating layer 141 and a second bonding insulating layer 142.

The lower transistor TR1 may include a source area 112, a drain area 113, a first gate insulating layer 114, and a gate electrode 115. The capacitor 150 may include a storage node electrode 151, a dielectric layer 152, and a plate electrode 153.

The substrate 110 may include a semiconductor substrate such as a silicon wafer or a silicon on insulator (SOI) wafer. The substrate 110 may include a group III-V semiconductor substrate, for example, a substrate formed of a compound semiconductor such as GaAs. The substrate 110 may include single-crystalline silicon, polysilicon, amorphous silicon, single-crystalline silicon-germanium, polycrystalline silicon-germanium, carbon-doped silicon, or a combination thereof.

The substrate 110 may include a cell area CA and a peripheral area PA. Memory cells may be located in the cell area CA. The peripheral area PA may be formed around the cell area CA. Various contacts that connect a peripheral circuit, which supplies various signals and voltages to the memory cells, to the memory cells may be located in the peripheral area PA. For example, the through contact 190 that connects the bit line BL and the lower transistor TR1 is located in the peripheral area PA.

In the peripheral area PA, at least one element isolation layer 111 may be located in the substrate 110. The element isolation layer 111 may be formed by using a trench-type element isolation technique such as shallow trench isolation (STI). The element isolation layer 111 may include silicon oxide, silicon nitride, silicon oxynitride, a low-k dielectric, a high-k dielectric, or a combination thereof.

The lower transistor TR1 may be located on the substrate 110. In an embodiment, the lower transistor TR1 is one of transistors included in the peripheral circuit. The first contact 116 may be electrically connected to the source area 112 and the drain area 113 of the lower transistor TR1 formed in the substrate 110. In an area of the substrate 110 other than an area in which the lower transistor TR1 is located, the second contact 127, the lower wiring layer 122, the third contact 128, and the pad layer 123 may be sequentially arranged on the substrate 110. The lower wiring layer 122 may be electrically connected to the first contact 116 and the second contact 127. The pad layer 123 may be electrically connected to the third contact 128. The first insulating layer 120 may be located to cover the lower transistor TR1, the first contact 116, the second contact 127, the lower wiring layer 122, the third contact 128, and the pad layer 123.

The pad layer 123 may be electrically connected to the drain area 113 of the lower transistor TR1 through the first contact 116, the lower wiring layer 122, and the third contact 128. The second insulating layer 130 may be located on the pad layer 123. An upper surface of the pad layer 123 and a lower surface of the second insulating layer 130 may be flush with each other.

The first bonding insulating layer 141 may be located on the second semiconductor structure S2. The first bonding insulating layer 141 may be located between the first semiconductor structure S1 and the second semiconductor structure S2. The second bonding insulating layer 142 may be located under the first semiconductor structure S1. The second bonding insulating layer 142 may be located between the first bonding insulating layer 141 and the first semiconductor structure S1. In an embodiment, an upper surface of the first bonding insulating layer 141 and a lower surface of the second bonding insulating layer 142 are substantially flush with each other.

The first gate insulating layer 114 and the first insulating layer 120 may each include silicon oxide, silicon nitride, silicon oxynitride, a high-k dielectric, or a combination thereof. The gate electrode 115, the first contact 116, the second contact 127, the lower wiring layer 122, the third contact 128, and the pad layer 123 may each include a conductive material such as a metal, a metal oxide, a metal nitride, a metal silicide, polysilicon, conductive carbon, or a combination thereof. The bonding layer 140 may include silicon oxide, silicon nitride, silicon oxynitride, silicon carbonitride, a high-k dielectric, or a combination thereof.

The first semiconductor structure S1 may be located on the second bonding insulating layer 142. The first semiconductor structure S1 may be bonded to the second semiconductor structure S2 through the bonding layer 140.

The third insulating layer 154 may be located on the second bonding insulating layer 142. The capacitor 150 may be located in the third insulating layer 154. The capacitor 150 may be positioned in the cell area CA. In an embodiment, the dielectric layer 152 conformally covers the storage node electrode 151. The storage node electrode 151 and the plate electrode 153 may each include a conductive material such as metal, metal oxide, metal nitride, metal silicide, polysilicon, conductive carbon, or a combination thereof. The dielectric layer 152 may include a high-k dielectric material, silicon oxide, silicon nitride, or a combination thereof.

The fourth insulating layer 191 may be located on the third insulating layer 154. The channel structure 160 may be located on the storage node electrode 151. The channel structure 160 may extend in a vertical direction. The channel structure 160 may include a channel area formed in an area overlapping word lines WL or the back gate electrode 170 in the first direction FD. The channel structure 160 may include a source area or a drain area formed around the channel area. The channel structure 160 may include polysilicon or single-crystalline silicon.

Although not shown, a landing pad may be located between the channel structure 160 and the storage node electrode 151. The landing pad may correspond to a single channel structure 160. The landing pad may include a conductive material such as metal, metal nitride, metal silicide, polysilicon, conductive carbon, or a combination thereof. The landing pad may correspond to a single storage node electrode 151.

The second gate insulating layer 161 and the third gate insulating layer 162 may be located on side surfaces of the channel structure 160. The second gate insulating layer 161 may be located between the channel structure 160 and the corresponding word line WL in the first direction FD. The second gate insulating layer 161 may extend in the vertical direction. The third gate insulating layer 162 may be located between the channel structure 160 and the back gate electrode 170 in the first direction FD. The third gate insulating layer 162 may extend in the vertical direction. The second gate insulating layer 161 and the third gate insulating layer 162 may each include silicon oxide, silicon nitride, silicon oxynitride, silicon carbonitride, a high-k dielectric material, or a combination thereof.

The word lines WL, the first insulating pattern 181, and the second insulating pattern 182 may be arranged between the second gate insulating layers 161 facing each other. A vertical length of the word line WL may be less than that of the channel structure 160. The first insulating pattern 181 may be located between the word lines WL facing each other. The first insulating pattern 181 may cover one side surface and an upper surface of each word line WL. The second insulating pattern 182 may cover a lower surface of the first insulating pattern 181 and lower surfaces of the word lines WL.

The back gate electrode 170, the second gate capping layer 171, and the third insulating pattern 183 may be arranged between the third gate insulating layers 162 facing each other. A vertical length of the back gate electrode 170 may be less than that of the channel structure 160. The back gate electrode 170 may be located between the second gate capping layer 171 and the third insulating pattern 183. The second gate capping layer 171, the back gate electrode 170, and the third insulating pattern 183 may overlap in the vertical direction.

The word line WL and the back gate electrode 170 may each include a conductive material such as metal, metal nitride, metal silicide, polysilicon, conductive carbon, or a combination thereof. The first insulating pattern 181, the second insulating pattern 182, the third insulating pattern 183, and the second gate capping layer 171 may each include silicon oxide, silicon nitride, silicon oxynitride, silicon carbonitride, a high-k dielectric material, or a combination thereof.

The bit line contact 194 may be located on the channel structure 160. The bit line contact 194 may be located in the fifth insulating layer 192. The fifth insulating layer 192 may be located on the fourth insulating layer 191. The fifth insulating layer 192 may include silicon oxide, silicon nitride, silicon oxynitride, silicon carbonitride, a high-k dielectric material, or a combination thereof. The bit line contact 194 may include a conductive material such as metal, metal oxide, metal nitride, metal silicide, polysilicon, conductive carbon, or a combination thereof.

The sixth insulating layer 193, the bit line BL, the first wiring layer 195, the wiring contact 197, and the first upper contact 201 may be arranged on the fifth insulating layer 192. The bit line BL may be located in the sixth insulating layer 193. The bit line BL may be located on the bit line contact 194. The bit line BL may be connected to the channel structure 160 through the bit line contact 194. For example, the bit line BL may be positioned on one side or end of the vertical channel structure 160 while the capacitor 150 is positioned on the opposite side or end. The bit line BL may be positioned in the same layer as the first wiring layer 195. The bit line BL may extend in the first direction FD. The bit line BL may include a conductive material such as metal, metal nitride, metal silicide, polysilicon, conductive carbon, or a combination thereof. In an embodiment, the first wiring layer 195 includes the same material as the bit line BL.

The wiring contact 197 may be located on the first wiring layer 195. The first wiring layer 195 may extend from the cell area CA to the peripheral area PA. The lower contact 196 may be located such that one side thereof is in contact with a lower surface of the first wiring layer 195 and a remaining side thereof is in contact with an upper surface of the plate electrode 153. In the peripheral area PA, the through contact 190 may be located such that one side thereof is in contact with the lower surface of the first wiring layer 195 and a remaining side thereof is in contact with the upper surface of the pad layer 123. The through contact 190 may penetrate the bonding layer 140.

The first upper contact 201 may be positioned on the bit line BL. In an embodiment, the first upper contact 201 corresponds to a connection contact. In an embodiment, a first distance W1 between an upper surface and a lower surface of the first upper contact 201 is shorter than a second distance W2 from a lower surface of the bit line BL to a lower surface of the channel structure 160.

The seventh insulating layer 199, the first upper wiring layer 202, and the second wiring layer 198 may be arranged on the sixth insulating layer 193. The first upper wiring layer 202 may be positioned on the first upper contact 201. The first wiring layer 195 may be positioned between the layer in which the plate electrode 153 is located and the first upper wiring layer 202. The second wiring layer 198 may be positioned on the wiring contact 197. The second wiring layer 198 may be positioned in the same layer as the first upper wiring layer 202.

Referring to FIG. 1, a cross-sectional structure of a semiconductor device according to an embodiment of present disclosure may be configured to form the bit line BL on the opposite side to where the capacitor 150 may be formed, in reference to the channel structure level (also referred to “first level”). The first level LV1 may refer to the level where a channel structure 160 may be formed. The bit line BL may be formed on a second level LV2, wherein the second level LV2 may be on one side of the first level LV1 (e.g., above the first level LV1). Meanwhile the capacitor 150 may be formed on a third level LV3, wherein the third level LV3 may be opposite side of the first level LV1 (e.g., below the first level LV1).

A first upper wiring layer 202 may be disposed on the cell region CA at a fourth level LV4, wherein the fourth level may be higher than the second level LV2. A substrate 110 may be disposed on a fifth level LV5 in the cell region CA and the peripheral region PA, wherein the fifth level LV5 may be lower than the third level LV3.

The first distance W1 may represent a distance between a bottom of the fourth level LV4 and a top of the second level LV2. The second distance W2 may represent a distance between a bottom of the second level LV2 and a top of the third level LV3.

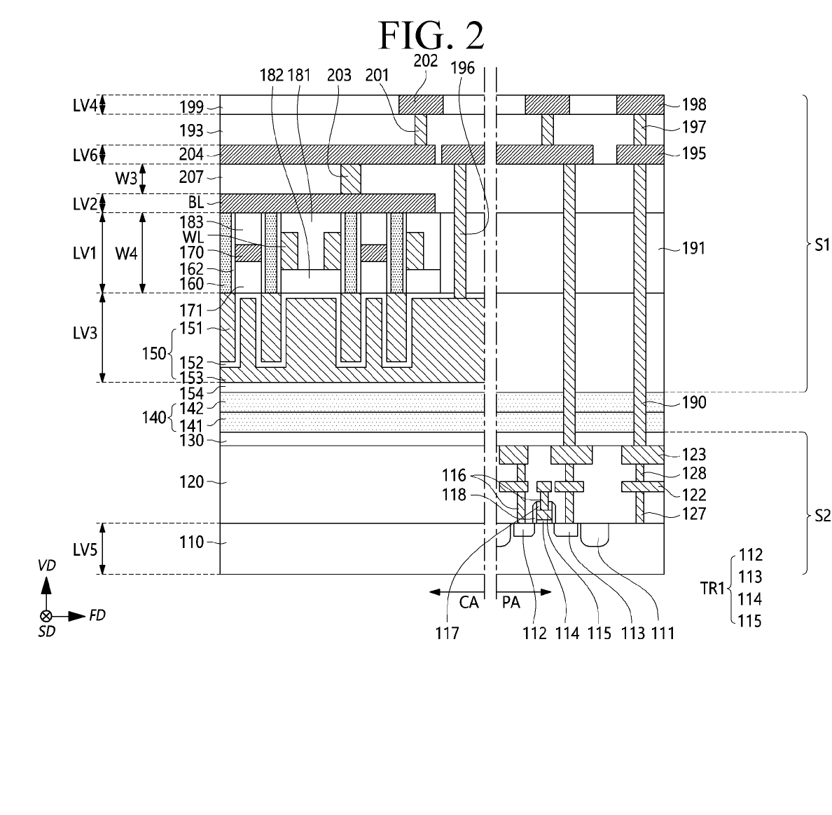

FIG. 2 is a diagram illustrating another example of the cross-sectional structure of the semiconductor device according to an embodiment.

Referring to FIG. 2, the semiconductor device according to an embodiment may include a second semiconductor structure S2, a first semiconductor structure S1, a bonding layer 140, and a through contact 190.

The first semiconductor structure S1 may include a third insulating layer 154, a capacitor 150, a channel structure 160, a second gate insulating layer 161, a third gate insulating layer 162, a back gate electrode 170, a second gate capping layer 171, a first insulating pattern 181, a second insulating pattern 182, a third insulating pattern 183, a word line WL, a fourth insulating layer 191, an eighth insulating layer 207, a sixth insulating layer 193, a bit line BL, a lower contact 196, a wiring contact 197, a seventh insulating layer 199, upper contacts 201 and 203, upper wiring layers 202 and 204, and wiring layers 195 and 198. For example, in FIG. 2, the bit line BL may be positioned on one side or end of the vertical channel structure 160 while the capacitor 150 is positioned on the opposite side or end.

The second upper contact 203 may be located on the bit line BL. In an embodiment, the second upper contact 203 corresponds to a connection contact. In an embodiment, the second upper contact 203 is in direct contact with an upper surface of the bit line BL. The second upper contact 203 may be located in an eighth insulating layer 207. A distance third W3 between an upper surface and a lower surface of the second upper contact 203 may be less than a fourth distance W4 from a lower surface of the bit line BL to a lower surface of the channel structure 160.

The sixth insulating layer 193, the first wiring layer 195, the second upper wiring layer 204, and the first upper contact 201 may be located on the eighth insulating layer 207. In an embodiment, the second upper wiring layer 204 is connected to the bit line BL through the first upper contact 201 and the second upper contact 203. In the present specification, a wiring layer located on and connected to the bit line BL may be referred to as a connection wiring layer. In an embodiment, the second upper wiring layer 204 corresponds to a connection wiring layer. The second upper wiring layer 204 may be located on the second upper contact 203. The second upper wiring layer 204 may be positioned in the same layer as the first wiring layer 195. The first upper contact 201 may be located on the second upper wiring layer 204.

The seventh insulating layer 199, the first upper wiring layer 202, and the second wiring layer 198 may be located on the sixth insulating layer 193. The first upper wiring layer 202 may be located on the first upper contact 201. The first upper wiring layer 202 may be positioned in the same layer as the second wiring layer 198.

The second upper wiring layer 204 may be disposed on the cell region CA at a sixth level LV6, wherein the sixth level LV6 may be located between the second level LV2 and the fourth level LV4.

The third distance W3 may represent a distance between a bottom of the sixth level LV6 and a top of the second level LV2. The fourth distance W4 may represent a distance between the first level LV1 and a top of the third level LV3.

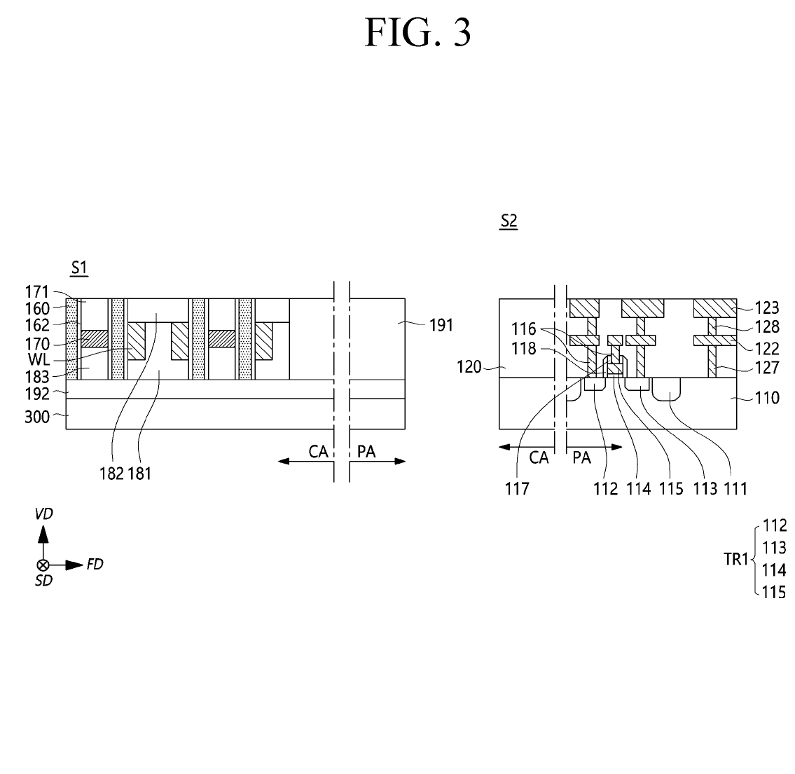

FIGS. 3-11 are diagrams illustrating an example of a method of manufacturing the semiconductor device according to an embodiment disclosed in FIG. 1.

Referring to FIG. 3, the first semiconductor structure S1 and the second semiconductor structure S2 are prepared. The first semiconductor structure S1 and the second semiconductor structure S2 may be different wafers.

The first semiconductor structure S1 may include a first substrate 300, the fifth insulating layer 192 formed on the first substrate 300, and the fourth insulating layer 191, the channel structure 160, the second gate insulating layer 161, the third gate insulating layer 162, the word line WL, the back gate electrode 170, the second gate capping layer 171, the first insulating pattern 181, the second insulating pattern 182, and the third insulating pattern 183 that are formed on/over the fifth insulating layer 192.

The second semiconductor structure S2 may include the substrate 110, the element isolation layer 111 formed in the substrate 110, and the lower transistor TR1, the second contact 127, the lower wiring layer 122, the third contact 128, the pad layer 123, and the first insulating layer 120 that are formed on/over the substrate 110. The first insulating layer 120 may include multiple layers.

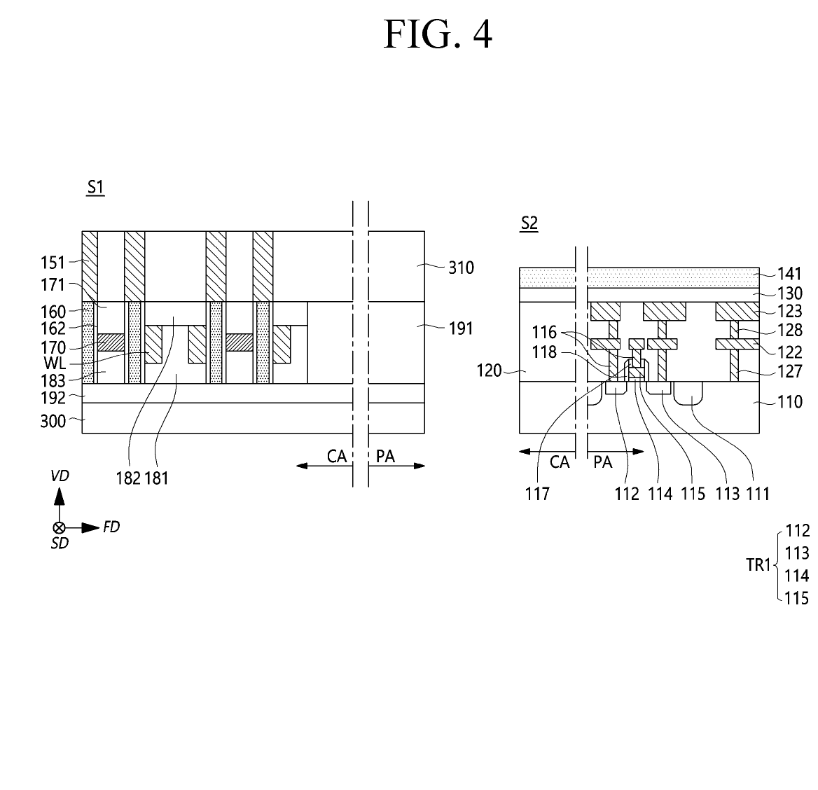

Referring to FIG. 4, a capacitor insulating layer 310 may be formed on the fourth insulating layer 191 of the first semiconductor structure S1. In an embodiment, the capacitor insulating layer 310 includes oxide. The storage node electrode 151 may be formed on the channel structure 160. The storage node electrode 151 may be formed in the capacitor insulating layer 310. Although not shown, a landing pad may be located between the channel structure 160 and the storage node electrode 151.

The second insulating layer 130 may be formed on the first insulating layer 120 of the second semiconductor structure S2. The first bonding insulating layer 141 may be formed on the second insulating layer 130 of the second semiconductor structure S2. In an embodiment, the first bonding insulating layer 141 includes silicon carbonitride.

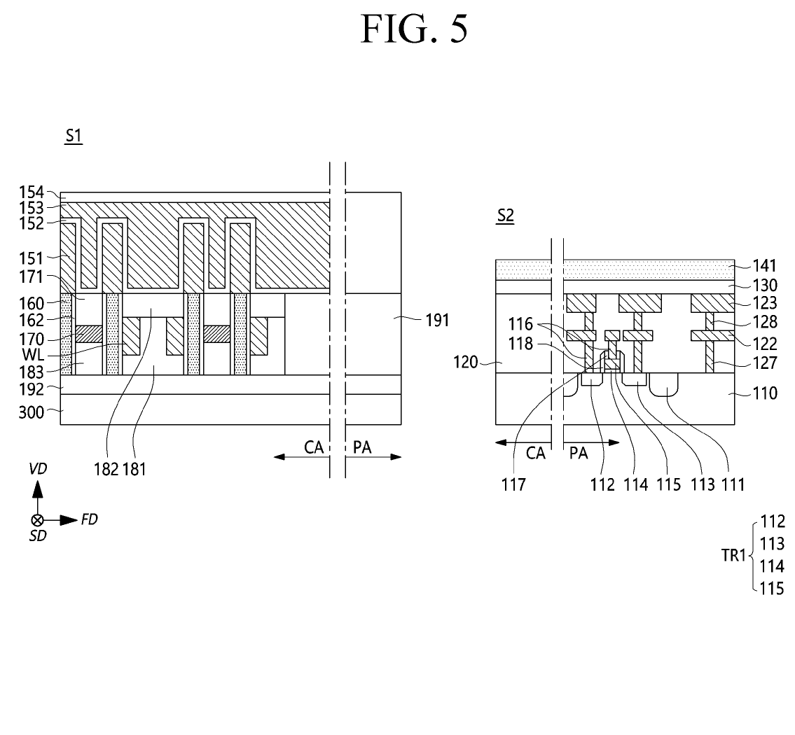

Referring to FIG. 5, the capacitor insulating layer 310 of the first semiconductor structure S1 may be removed. In an embodiment, the capacitor insulating layer 310 is removed through a wet etching process. The dielectric layer 152 may be formed in the cell area CA. In an embodiment, the dielectric layer 152 is formed to conformally cover the storage node electrode 151. The plate electrode 153 may be formed on the dielectric layer 152. The dielectric layer 152 and the plate electrode 153 may not be located in the peripheral area PA. The third insulating layer 154 may be formed on the upper surface of the plate electrode 153 and on the fourth insulating layer 191 in the peripheral area PA.

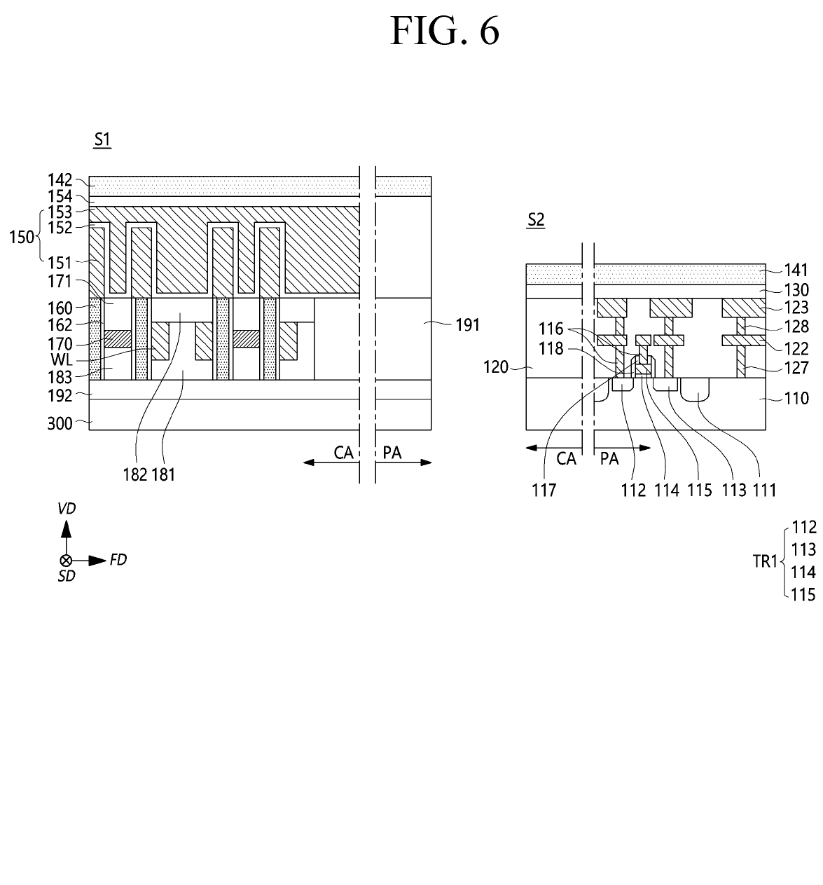

Referring to FIG. 6, the second bonding insulating layer 142 may be formed on the third insulating layer 154 of the first semiconductor structure S1.

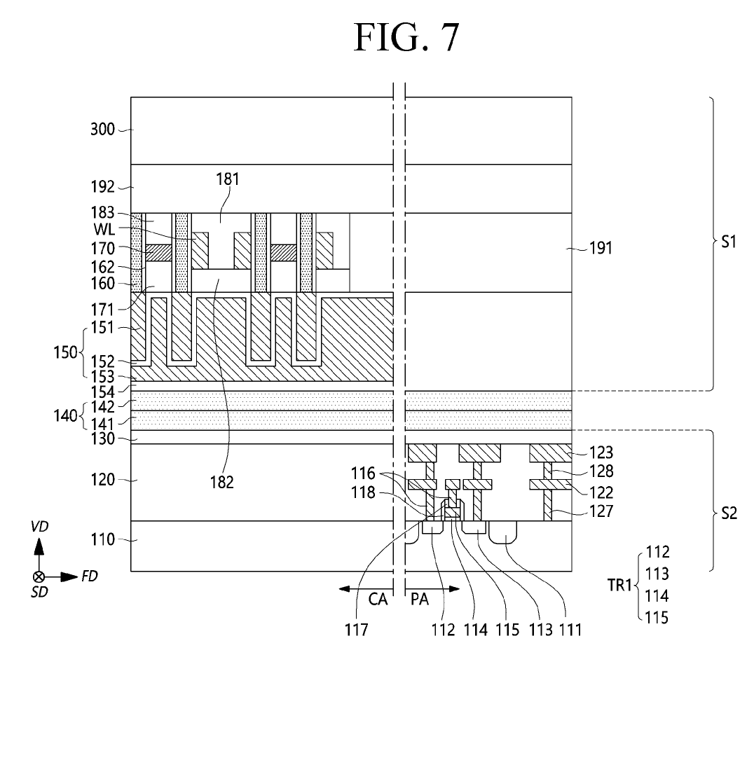

Referring to FIG. 7, the first semiconductor structure S1 may be bonded to the second semiconductor structure S2. In an embodiment, a process of bonding the second semiconductor structure S2 and the first semiconductor structure S1 includes bringing the second bonding insulating layer 142 into contact with the upper surface of the first bonding insulating layer 141, and applying heat to the first and second bonding insulating layers 141 and 142.

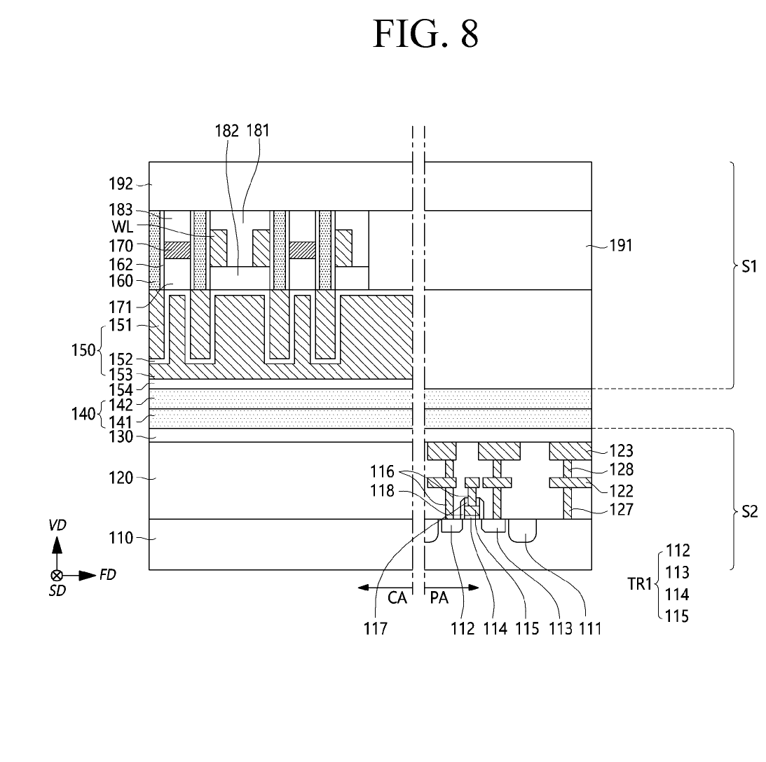

Referring to FIG. 8, the first substrate 300 may be removed. In an embodiment, the first substrate 300 is removed through a grinding process or a chemical mechanical polishing (CMP) process. A portion of the fifth insulating layer 192 may be removed. In an embodiment, a portion of the fifth insulating layer 192 is removed through a CMP process. Accordingly, a subsequent exposure process may be easily performed.

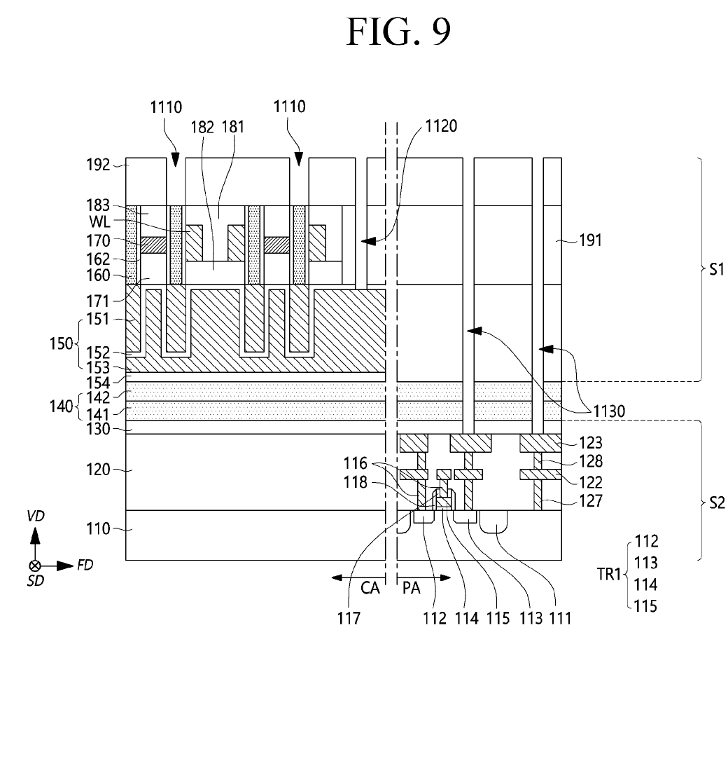

Referring to FIG. 9, a first through hole 1110 and a second through hole 1120 may be formed in the cell area CA. The first through hole 1110 may penetrate the fifth insulating layer 192 in the vertical direction to expose a surface of the channel structure 160. The second through hole 1120 may penetrate the fifth insulating layer 192 and the fourth insulating layer 191 in the vertical direction to expose the upper surface of the plate electrode 153.

A third through hole 1130 may be formed in the peripheral area PA. The third through hole 1130 may penetrate the second insulating layer 130, the bonding layer 140, the third insulating layer 154, the fourth insulating layer 191, and the fifth insulating layer 192 in the vertical direction to expose the upper surface of the pad layer 123.

Processes of forming the first through hole 1110, the second through hole 1120, and the third through hole 1130 may each include an anisotropic etching process. The processes of forming the first through hole 1110, the second through hole 1120, and the third through hole 1130 may be performed in the same process operation.

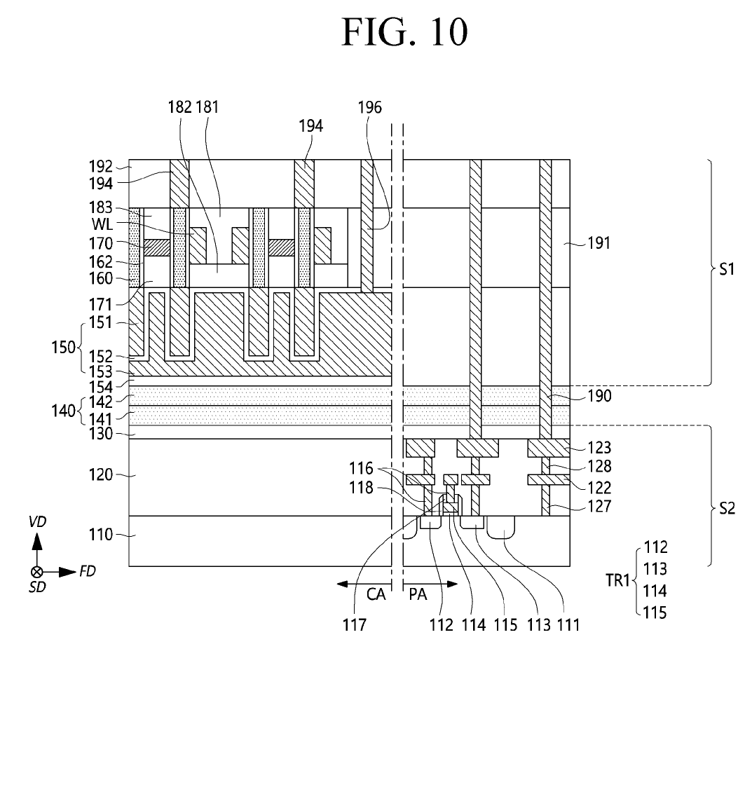

Referring to FIG. 10, conductive material may be charged into the first through hole 1110, the second through hole 1120, and the third through hole 1130, thus forming the bit line contact 194, the lower contact 196, and the through contact 190.

In an embodiment, the bit line contact 194 includes a barrier metal. In an embodiment, the bit line contact 194 includes tungsten. A lower surface of the bit line contact 194 may be in contact with an upper surface of the channel structure 160. Because the bit line contact 194 is relatively short, an overlay margin of the bit line BL with respect to the bit line contact 194 may be secured. As the capacitor 150 is formed first and the bit line contact 194 and the bit line BL are subsequently formed, the overlay margin of the bit line BL with respect to the bit line contact 194 may be secured.

A lower surface of the lower contact 196 may be in contact with the upper surface of the plate electrode 153. A lower surface of the through contact 190 may be in contact with the upper surface of the pad layer 123.

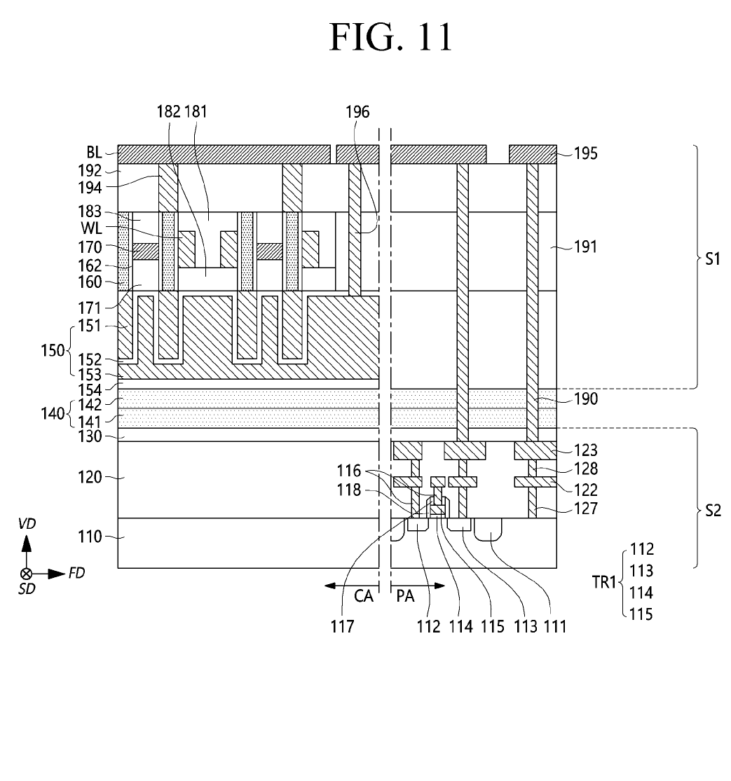

Referring to FIG. 11, the bit line BL may be formed on the bit line contact 194. The first wiring layer 195 may be formed on the lower contact 196 and the through contact 190. The first wiring layer 195 may extend from the cell area CA to the peripheral area PA.

Referring again to FIG. 1, the sixth insulating layer 193 may be formed on the fifth insulating layer 192. In an embodiment, the sixth insulating layer 193 includes oxide.

The first upper contact 201 may be formed on the bit line BL. In an embodiment, the first upper contact 201 corresponds to a connection contact. In an embodiment, the first distance W1 between the upper surface and the lower surface of the first upper contact 201 is less than the second distance W2 from the lower surface of the bit line BL to the lower surface of the channel structure 160. Because the first distance W1 between the upper surface and the lower surface of the first upper contact 201 formed on the bit line BL is less than the second distance W2 from the lower surface of the bit line BL to the lower surface of the channel structure 160, an overlay margin of the first upper contact 201 with respect to the bit line BL may be secured. As the capacitor 150 is formed first and the bit line contact 194 and the bit line BL are subsequently formed, the overlay margin of the first upper contact 201 with respect to the bit line BL may be secured. The wiring contact 197 may be formed on the first wiring layer 195 in the peripheral area PA.

Referring again to FIG. 1, the seventh insulating layer 199 may be formed on the sixth insulating layer 193. The first upper wiring layer 202 may be formed on the first upper contact 201 in the seventh insulating layer 199. The second wiring layer 198 may be formed on the wiring contact 197 in the seventh insulating layer 199. In an embodiment, the first upper wiring layer 202 and the second wiring layer 198 are formed through a CMP process. In an embodiment, each of the first upper wiring layer 202 and the second wiring layer 198 includes a barrier metal film. In an embodiment, each of the first upper wiring layer 202 and the second wiring layer 198 includes a conductive material.

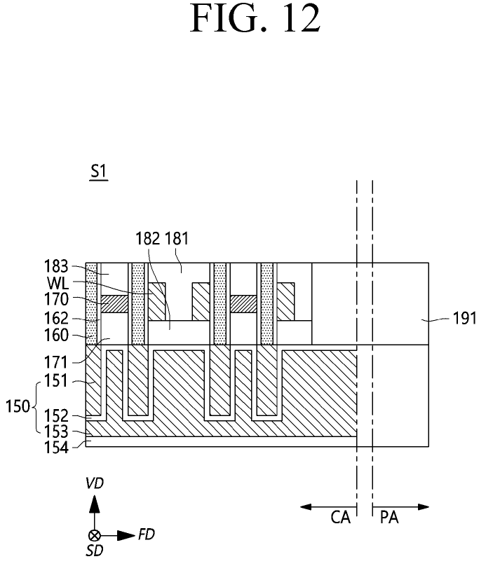

FIGS. 12-19 are diagrams illustrating an example of a method of manufacturing the semiconductor device according to the embodiment disclosed in FIG. 2.

The semiconductor device shown in FIG. 12 may be formed by the same method as the method of manufacturing the semiconductor device described with reference to FIGS. 3-5.

Referring to FIGS. 5 and 12, the first semiconductor structure S1 may be rotated by 180 degrees. The first substrate 300 and the fifth insulating layer 192 of the first semiconductor structure S1 may be removed. In an embodiment, the first substrate 300 is removed through a CMP process and a wet etching process. In an embodiment, the fifth insulating layer 192 is removed through a wet etching process.

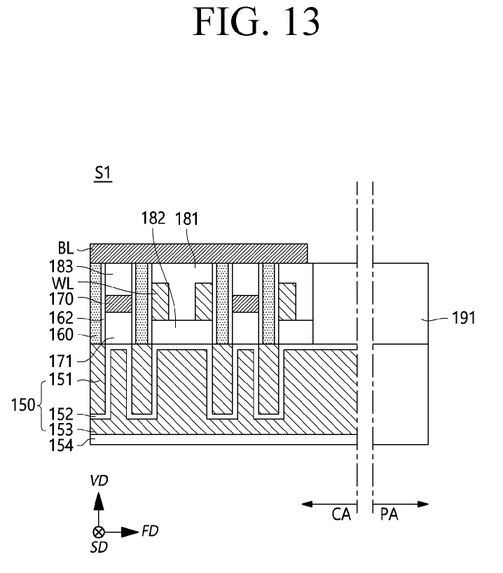

Referring to FIG. 13, the bit line BL may be formed on the fourth insulating layer 191 of the first semiconductor structure S1.

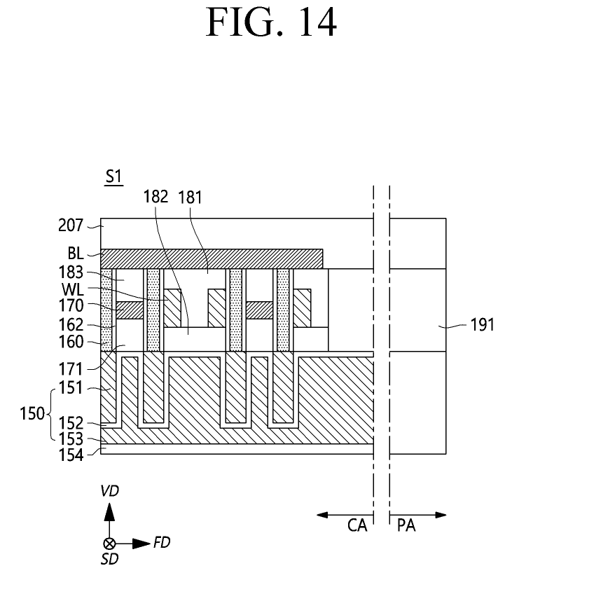

Referring to FIG. 14, the eighth insulating layer 207 may be formed on the fourth insulating layer 191 of the first semiconductor structure S1. In an embodiment, the eighth insulating layer 207 includes nitride and oxide.

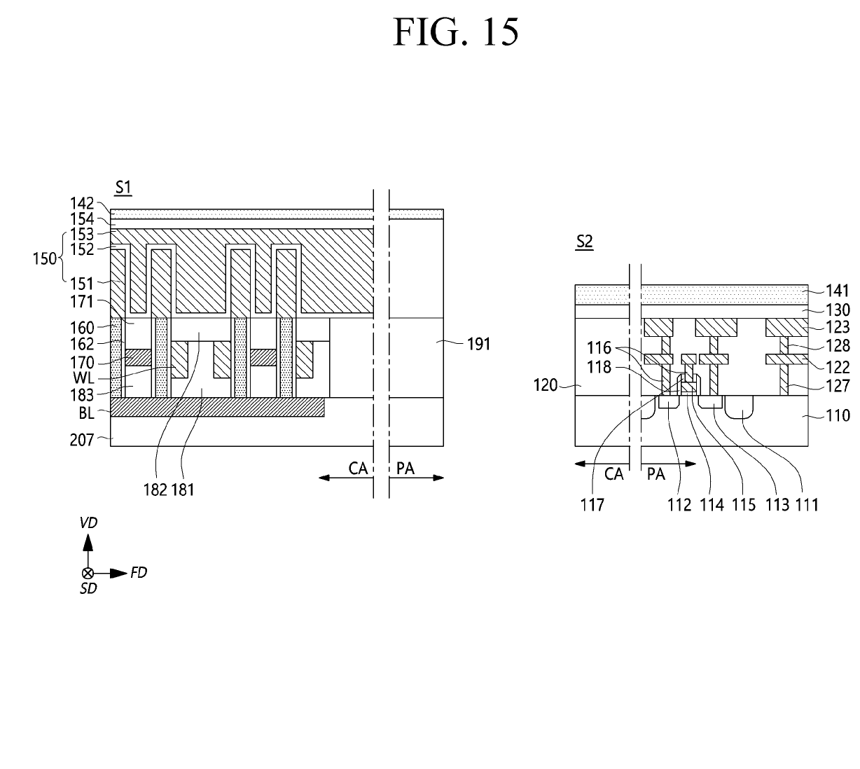

Referring to FIG. 15, the first semiconductor structure S1 may be rotated by 180 degrees. The second bonding insulating layer 142 may be formed on the third insulating layer 154 of the first semiconductor structure S1. Although not shown, an oxide layer may further be included below the second bonding insulating layer 142.

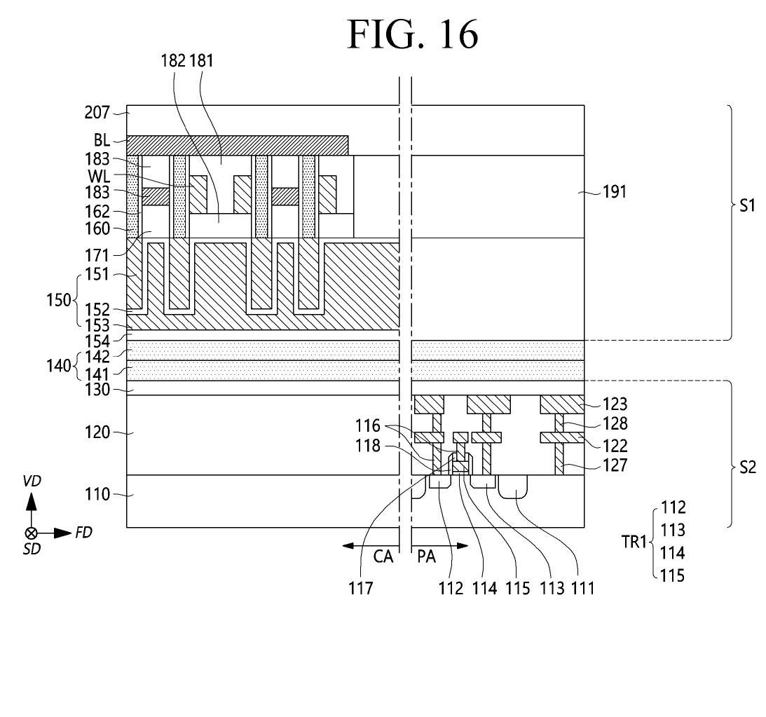

Referring to FIG. 16, the first semiconductor structure S1 may be rotated by 180 degrees. The first semiconductor structure S1 may be bonded to the second semiconductor structure S2. In an embodiment, a process of bonding the second semiconductor structure S2 and the first semiconductor structure S1 includes bringing the second bonding insulating layer 142 into contact with the upper surface of the first bonding insulating layer 141 and applying heat to the first and second bonding insulating layers 141 and 142.

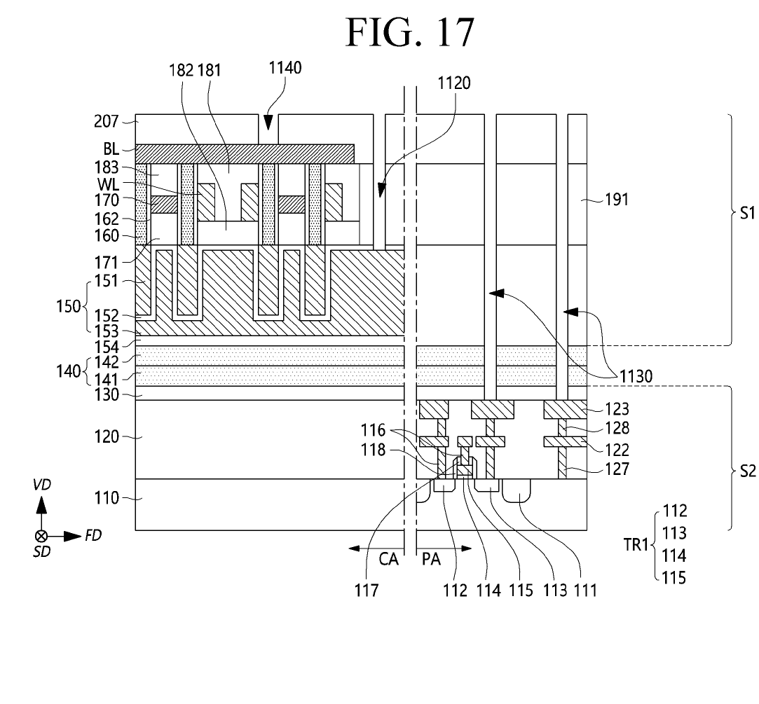

Referring to FIG. 17, a fourth through hole 1140 and the second through hole 1120 may be formed in the cell area CA. The fourth through hole 1140 may penetrate the eighth insulating layer 207 in the vertical direction to expose the upper surface of the bit line BL. The second through hole 1120 may penetrate the eighth insulating layer 207 and the fourth insulating layer 191 in the vertical direction to expose the upper surface of the plate electrode 153. In an embodiment, the fourth through hole 1140 is formed by the same method as the first through hole 1110.

The third through hole 1130 may be formed in the peripheral area PA. The third through hole 1130 may penetrate the second insulating layer 130, the bonding layer 140, the third insulating layer 154, the fourth insulating layer 191, and the eighth insulating layer 207 in the vertical direction to expose the upper surface of the pad layer 123.

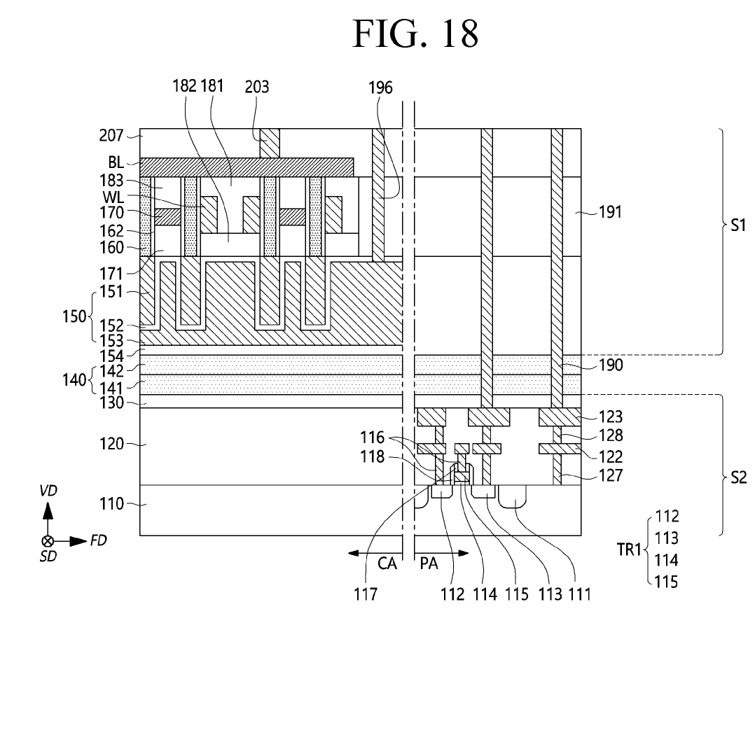

Referring to FIG. 18, conductive material may be charged into the fourth through hole 1140, the second through hole 1120, and the third through hole 1130, thus forming the second upper contact 203, the lower contact 196, and the through contact 190. In an embodiment, the second upper contact 203, the lower contact 196, and the through contact 190 are formed by depositing conductive material and performing a CMP process. The lower surface of the second upper contact 203 may be in contact with the upper surface of the bit line BL. In an embodiment, the second upper contact 203 corresponds to a connection contact.

Because the capacitor 150 is formed below the bit line BL, the third distance W3 between the upper surface and the lower surface of the second upper contact 203 may be less than the fourth distance W4 from the lower surface of the bit line BL to the lower surface of the channel structure 160. Accordingly, an overlay margin of the second upper contact 203 with respect to the bit line BL, which is formed on the bit line BL, may be increased.

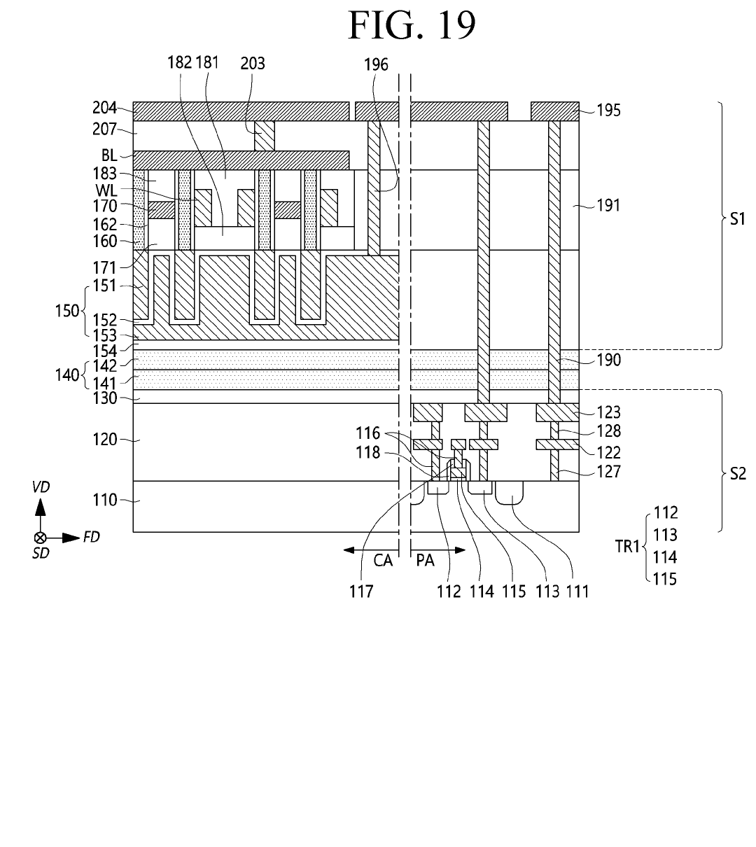

Referring to FIG. 19, the second upper wiring layer 204 may be formed on the eighth insulating layer 207. The second upper wiring layer 204 may be formed on the second upper contact 203. In an embodiment, the second upper wiring layer 204 is formed through a damascene process.

Referring again to FIG. 2, the sixth insulating layer 193 may be formed on the eighth insulating layer 207. The first upper contact 201 may be formed on the second upper wiring layer 204.

The seventh insulating layer 199 may be formed on the sixth insulating layer 193. The first upper wiring layer 202 may be formed on the first upper contact 201. The first upper wiring layer 202 may be formed through a damascene process. The first upper wiring layer 202 may be located in the same layer as the second wiring layer 198.

The above description is merely illustrative of the technical spirit of the present disclosure, and various modifications and changes may be made thereto by those skilled in the art without departing from the essential characteristics of the present disclosure. Furthermore, various embodiments are not intended to limit the technical spirit of the present disclosure but to illustrate the technical spirit of the present disclosure, and the technical spirit of the present disclosure is not limited by these embodiments.

What is claimed is:

1. A semiconductor device comprising:
a first semiconductor structure; and
a second semiconductor structure bonded to the first semiconductor structure;
wherein the first semiconductor structure comprises:
a capacitor including a plate electrode disposed in a plate electrode layer;
a channel structure disposed on the capacitor to extend in a vertical direction;
a bit line spaced apart from the capacitor in the vertical direction and disposed on the channel structure and in a bit line layer;
a first upper wiring layer disposed on the bit line;
a first wiring layer positioned between the first upper wiring layer and the plate electrode layer; and
a lower contact connecting the plate electrode and the first wiring layer.

2. The semiconductor device according to claim 1, further comprising a connection contact disposed on the bit line,
wherein a distance between an upper surface and a lower surface of the connection contact is less than a distance between a lower surface of the bit line and a lower surface of the channel structure.

3. The semiconductor device according to claim 2, wherein the connection contact is in direct contact with an upper surface of the bit line.

4. The semiconductor device according to claim 1, further comprising a bit line contact disposed between the bit line and the channel structure, including an upper surface in contact with a lower surface of the bit line,
wherein a lower surface of the bit line contact is in contact with an upper surface of the channel structure.

5. The semiconductor device according to claim 4, wherein the first wiring layer is located in the bit line layer.

6. The semiconductor device according to claim 5, further comprising a through contact penetrating a bonding layer, the through contact including one end in contact with a lower surface of the first wiring layer,
wherein the second semiconductor structure comprises:
a substrate; and
a pad layer disposed on the substrate, and
wherein the other end of the through contact is in contact with an upper surface of the pad layer.

7. The semiconductor device according to claim 5, wherein the first wiring layer includes a same material as the bit line.

8. The semiconductor device according to claim 1, wherein a lower surface of the bit line is in contact with an upper surface of the channel structure.

9. The semiconductor device according to claim 8, further comprising a connection wiring layer located on the bit line and electrically connected to the bit line.

10. The semiconductor device according to claim 9, wherein the connection wiring layer is located in a same layer as the first wiring layer.

11. A semiconductor device comprising:
a substrate;
a first upper wiring layer disposed on the substrate;
a capacitor positioned between the substrate and the first upper wiring layer, the capacitor including a plate electrode;
a channel structure disposed on the capacitor to extend in a vertical direction;
a bit line spaced apart from the capacitor in the vertical direction and disposed on the channel structure;
a first wiring layer positioned between the first upper wiring layer and a layer in which the plate electrode is located; and
a lower contact connecting the plate electrode and the first wiring layer.

12. The semiconductor device according to claim 11, further comprising a connection contact disposed on the bit line,
wherein a distance between an upper surface and a lower surface of the connection contact is less than a distance between a lower surface of the bit line and a lower surface of the channel structure.

13. The semiconductor device according to claim 12, wherein the connection contact is in direct contact with an upper surface of the bit line.

14. The semiconductor device according to claim 11, further comprising a bit line contact disposed between the bit line and the channel structure, including an upper surface in contact with a lower surface of the bit line,
wherein a lower surface of the bit line contact is in contact with an upper surface of the channel structure.

15. The semiconductor device according to claim 14, wherein the first wiring layer is located in a same layer as the bit line.

16. The semiconductor device according to claim 15, further comprising a through contact including one side in contact with a lower surface of the first wiring layer,
wherein a remaining side of the through contact is in contact with an upper surface of a pad layer positioned between an upper surface of the substrate and a lower surface of the plate electrode.

17. The semiconductor device according to claim 15, wherein the first wiring layer includes a same material as the bit line.

18. The semiconductor device according to claim 11, wherein a lower surface of the bit line is in contact with an upper surface of the channel structure.

19. The semiconductor device according to claim 18, further comprising a connection wiring layer located on the bit line and electrically connected to the bit line.

20. The semiconductor device according to claim 19, wherein the connection wiring layer is located in a same layer as the first wiring layer.

21. A semiconductor device comprising:
a first semiconductor structure;
a second semiconductor structure bonded to the first semiconductor structure; and
wherein the first semiconductor structure comprises a cell region and a peripheral region,
wherein the cell region of the first semiconductor structure comprises:
a channel structure formed at a first level;
a bit line disposed on a second level, wherein the second level is higher than the first level; and
a capacitor disposed on a third level, wherein the third level is lower than the first level.

22. The semiconductor device according to claim 21,
wherein the cell region of the first semiconductor structure further comprises:
a bit line contact disposed on the channel structure and connected between the channel structure and the bit line.

23. The semiconductor device according to claim 22,
wherein the first semiconductor structure further comprises:
a first upper wiring layer disposed on the cell region at a fourth level, wherein the fourth level is higher than the second level; and
a first wiring layer disposed on the cell region and extended into the peripheral region in a horizontal direction at the second level,
wherein the first upper wiring layer is connected to the bit line through an upper contact in a vertical direction; and
wherein the first wiring layer in the cell region is connected to the capacitor through a lower contact in the vertical direction.

24. The semiconductor device according to claim 23,
wherein the second semiconductor structure further includes:
a substrate disposed on a fifth level in the cell region and the peripheral region, wherein the fifth level is lower than the third level; and
a second wiring layer disposed on the fourth level in the peripheral region,
wherein the first wiring layer in the peripheral region is connected to the substrate through a through contact in the vertical direction,
wherein the first wiring layer in the peripheral region is further connected to the second wiring layer through a wiring contact in the vertical direction.

25. The semiconductor device according to claim 23,
wherein a first distance is a distance between a bottom of the fourth level and a top of the second level,
wherein a second distance is a distance between a bottom of the second level and a top of the third level,
wherein the first distance is shorter than the second distance.

26. The semiconductor device according to claim 21,
wherein the first semiconductor structure further comprises:
a first upper wiring layer disposed on the cell region at a fourth level, wherein the fourth level is higher than the second level;
a second upper wiring layer disposed on the cell region at a sixth level, wherein the sixth level is between the second level and the fourth level; and
a first wiring layer disposed on the cell region at the second level and extended into the peripheral region in a horizontal direction,
wherein the first upper wiring layer is connected to the second upper wiring layer through a first upper contact in a vertical direction,
wherein the second upper wiring layer is connected to the bit line through a second upper contact in the vertical direction,
wherein the first wiring layer in the cell region is connected to the capacitor through a lower contact in the vertical direction.

27. The semiconductor device according to claim 26,
wherein the second semiconductor structure further includes:
a substrate disposed on a fifth level in the cell region and the peripheral region, wherein the fifth level is lower than the third level; and
a second wiring layer disposed on the fourth level in the peripheral region,
wherein the first wiring layer in the peripheral region is connected to the substrate through a through contact in the vertical direction,
wherein the first wiring layer in the peripheral region is connected to the second wiring layer through a wiring contact in the vertical direction.

28. The semiconductor device according to claim 26,
wherein a third distance is a distance between a bottom of the sixth level and a top of the second level,
wherein a fourth distance is a distance between the first level and a top of the third level,
wherein the third distance is shorter than the fourth distance.
